(19) United States
(12) Patent Application Publication
(10) Pub. No.: US 2013/0329378 A1
(43) Pub. Date: Dec. 12, 2013

(54) Universal Serial Bus Device with Improved Package Structure and Method Thereof

(71) Applicant: GERARD TECHNOLOGIES (SUZHOU) CO., LTD., Suzhou City (CN)

(72) Inventors: Jian-Fei Hou, Suzhou City (CN); Jian Xu, Suzhou City (CN)

(73) Assignee: Gerard Technologies (Suzhou) Co., Ltd., Suzhou City (CN)

(21) Appl. No.: 13/869,010

(22) Filed: Apr. 23, 2013

(30) Foreign Application Priority Data
Jun. 6, 2012 (CN) 201210183767.3

(51) Int. Cl. H05K 7/00; H05K 3/36; H05K 3/34

(52) U.S. Cl. CPC H05K 7/00; H05K 3/34; H05K 3/36
USPC 361/736; 29/840; 29/830

(57) ABSTRACT

A Universal Serial Bus device includes a PCB module, a plastic package shell and a power module. The PCB module includes a PCB, and a storage chip and a control chip both arranged on the PCB module. The PCB includes opposite front end and rear end, and opposite upper surface and lower surface. The upper surface has a number of contacting portions, and the storage chip and the control chip being arranged on the lower surface. The plastic package shell at least encapsulates the lower surface of the PCB to encapsulate the storage chip and the control chip. The power module is electrically connected to the part of the PCB module where is not encapsulated by the plastic package shell.

### BACKGROUND OF THE INVENTION

1. Field of the Invention

The present invention relates to a Universal Serial Bus device, more particularly to a USB flash drive.

2. Description of Related Art

Universal Serial Bus (USB) is a standard of Serial Bus for connecting a computer system and an outer device, and also a technical regulation for input-output ports. Hence, USB is widely used in info-communication products, such as personal computers and portable devices etc, also extended into other related fields, such as photographic equipments, digital TV (Set Top Box, STB), and game machines.

Since USB 1.0 version was released in 1996, currently USB 3.0 was just released after USB 1.1 and 2.0. The main difference between different USB versions is the maximum transmission speed. The transmission speed of the earliest USB 1.0 is 1.5 Mbps (192 KB/s), and mainly used for man-machine port devices, such as keyboards, mouse, and rocking levers. The transmission speed of USB 1.1 version released in 1998 reached to 12 Mpbs (1.5 MB/s), named full-speed USB. However, the transmission speed of USB 2.0 released in 2000 was improved a lot and reached to a high-speed of 480 Mbps (60 MB/s). The latest USB 3.0 has the transmission speed of 5 Gbps (640 MB/s), 10 times of USB. 2.0.

USB Flash Drive (UFD) is also named as U disk, which is a mini high-capacity portable storage product with USB port and without physical drive. The storage media of UFD is Flash Memory, which does not need additional drive and combine the drive and the storage media into one. Thus, UFD is capable of storing written and reading data independently when connecting with a USB port in a computer. Corresponding to the latest USB 3.0, the latest UFD is UFD 3.0.

Conventional manufacture of UFD 3.0 is to package a control chip, a storage chip, and power modules one by one, and then soldered to a Printed Circuit Board (PCB) separately. Finally, the PCB, the control chip, the storage chip and the power modules are packed by a plastic package shell integrally. The manufacture process is complex and the packed product is huge in volume and of high cost. Further, since the power modules and the control chip and the storage chip are packed together inside the plastic package shell, it is prone to producing cross talk among the power modules, the control chip and the storage chip when using. Especially, after long-term use, the heat-radiation ability of the power modules is influenced. Furthermore, since the power modules are integrated into the plastic package shell, when the power modules are out of use, the plastic package shell needs to be opened first, then find the power modules for replacement or maintenance, which is time consuming and complex for maintenance.

Hence, it is necessary to improve the conventional Universal Serial Bus device and the manufacture method thereof to address problems mentioned above.

### BRIEF SUMMARY OF THE INVENTION

Accordingly, an object of the present invention is to provide a Universal Serial Bus device which is of compact structure, and of lower cost.

Accordingly, another object of the present invention is to provide a manufacture method of manufacturing the Universal Serial Bus device.

In order to achieve the above-mentioned object, a Universal Serial Bus device comprises a PCB module, a plastic package shell and a power module. The PCB module comprises a PCB, and a storage chip and a control chip both arranged on the PCB module. The PCB comprises opposite front end and rear end, and opposite upper surface and lower surface. The upper surface has a plurality of contacting portions, and the storage chip and the control chip being arranged on the lower surface. The plastic package shell at least encapsulates the lower surface of the PCB to encapsulate the storage chip and the control chip. The power module is electrically connected to the part where is not encapsulated by the plastic package shell of the PCB module.

The foregoing has outlined rather broadly the features and technical advantages of the present invention in order that the detailed description of the invention that follows may be better understood. Additional features and advantages of the invention will be described hereinafter, which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an assembled, perspective view of a Universal Serial Bus device in accordance with a first embodiment of the present invention;

FIG. 2 is an exploded, perspective view of the Universal Serial Bus device of FIG. 1;

FIG. 3 is a perspective view of a first PCB of the Universal Serial Bus device shown in FIG. 1;

FIG. 4 is a perspective view of a second PCB of the Universal Serial Bus device shown in FIG. 1;

FIG. 5 is a flow chart of manufacturing the Universal Serial Bus device of FIG. 1;

FIG. 6 is an assembled, perspective view of a Universal Serial Bus device in accordance with a second embodiment of the present invention;

FIG. 7 is an exploded, perspective view of the Universal Serial Bus device shown in FIG. 6;

FIG. 8 is a perspective view of a first PCB of the Universal Serial Bus device shown in FIG. 6; and

FIG. 9 is a flow chart of manufacturing the Universal Serial Bus device of FIG. 6.

### DETAILED DESCRIPTION OF THE PREFERRED EMBODIMENTS

In the following description, numerous specific details are set forth to provide a thorough understanding of the present invention. However, it will be obvious to those skilled in the art that the present invention may be practiced without such specific details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

Reference will be made to the drawing figures to describe the present invention in detail, wherein depicted elements are not necessarily shown to scale and wherein like or similar elements are designated by same or similar reference numeral through the several views and same or similar terminology.

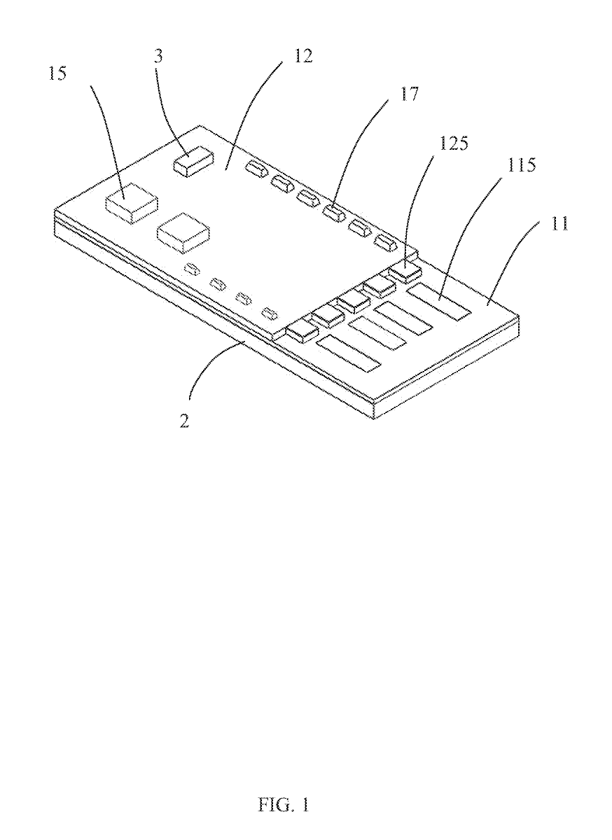

Please refer to FIGS. 1-4, a Universal Serial Bus device in accordance with a first embodiment of the present invention comprises a PCB module (not labeled), a plastic package shell 2 packing the PCB module and a power module 3 arranged on the PCB module and exposed to the outside.

The PCB module comprises a first PCB 11, a second PCB 12 electrically connecting with the first PCB 11, a storage chip 13, a control chip 14 and a crystal oscillator 15. The length of the second PCB 12 is shorter than that of the first PCB 11, dual-channel communication is realized by the first and second PCBs 11, 12.

The first PCB 11 comprises opposite first front end 111 and first rear end 112, opposite first upper surface 113 and first lower surface 114 extending between the first front and rear ends 111, 112, and four first contacting portions 115 formed on the first upper surface 113 and near to the first front end 111. Each first contacting portion 115 comprises a contacting surface 1151 exposed to the outside. In the preferred embodiment of the present invention, the contacting portions 115 are in the form of golden fingers, however, in an alternative embodiment, the contacting portions 115 also could be elastic metal pads (not shown) soldered to the first upper surface 113.

The second PCB 12 comprises opposite second front end 121 and second rear end 122, opposite second upper surface 123 and second lower surface 124 and five second contacting portions 125 aligned in a row behind the first contacting portions 115. Each second contacting portion 125 comprises a second contacting surface 1251 exposed to the outside and higher than the first contacting surface 1151 along the thickness direction of the first PCB 11. In the first embodiment of the present invention, the second contacting portion 125 is a slice and extends beyond the second front end 121 of the second PCB 12 to be attached the first upper surface 113 of the first PCB 11. In an alternative embodiment, the second contacting portion could be a metal pad (not shown) soldered to the second upper surface 123 or an elastic contacting pad soldered to the second upper surface 123. Further, the second lower surface 124 is soldered to the first upper surface 113 of the first PCB 11 via SMT (Surface Mounted Technology).

The storage chip 13 and the control chip 14 are soldered on the first lower surface 114 of the first PCB 11 via SMT (Surface Mounting Technology). In an alternative embodiment of the present invention, the storage chip 13 and the control chip 14 could be more than one.

The crystal oscillator 15 is soldered to the second upper surface 123 of the second PCB 12.

The first contacting portions 115 are close to the first front end 111 of the first PCB 11, and the arrangement of the first and second contacting portions 115, 125 are fulfill with the interface standard of USB 3.0. In the preferred embodiment of the present invention, the first PCB 11 and the second PCB 12 are soldered together to stack together, and the first contacting portions 115 and the second contacting portions 125 are formed directly on the first and second PCBs 11, 12 directly. Hence, the Universal Serial Bus device of the present invention has the advantages of simpler in structure, longer service life, and lower manufacture cost compared to the conventional USB device.

The plastic package shell 2 is disposed on the first lower surface 114 and encapsulates the storage chip 13 and the control chip 14. The first upper surface 113 is not encapsulated by the plastic package shell 2. Since the crystal oscillator 15 is arranged on the second upper surface 123, the crystal oscillator 15 is also exposed to the outside. The plastic package shell 2 is manufactured by injection molding technology.

The power module 3 is electrically connected to the second upper surface 123 of the second PCB 12 via SMT (Surface Mounting Technology), and exposed to the outside. Since the power module 3 is exposed to the outside, the Universal Serial Bus device of the present invention has the advantages of reduced total size, lower manufacture cost, higher heat-radiation ability, and convenient maintenance. Except the advantages mentioned above, the cross talk among signals is also depressed since the power module 3 and the storage chip 13, the control chip 14 are arranged on different surfaces.

It should be noticed that the reason that why the crystal oscillator 15 is exposed to the outside is same as that of the power module 3. Of course, the crystal oscillator 15 also could be arranged on the first lower surface 114, and encapsulated by the plastic package shell 2.

Except for the components described above, the PCB module further comprises a passive module 17 which comprises some capacitors (not labeled), some resistances (not labeled) etc. In the preferred embodiment of the present invention, the passive module 17 is also arranged on the second upper surface 123 of the second PCB 12 same as the power module 3 and the crystal oscillator 15 and exposed to the outside which can simplify the process and reduce the cost. Of course, in alternative embodiments, the passive component 17 also could be arranged on the first lower surface 114 of the first PCB 11 same as the storage chip 13 and the control chip 14, and encapsulated by the plastic package shell 2.

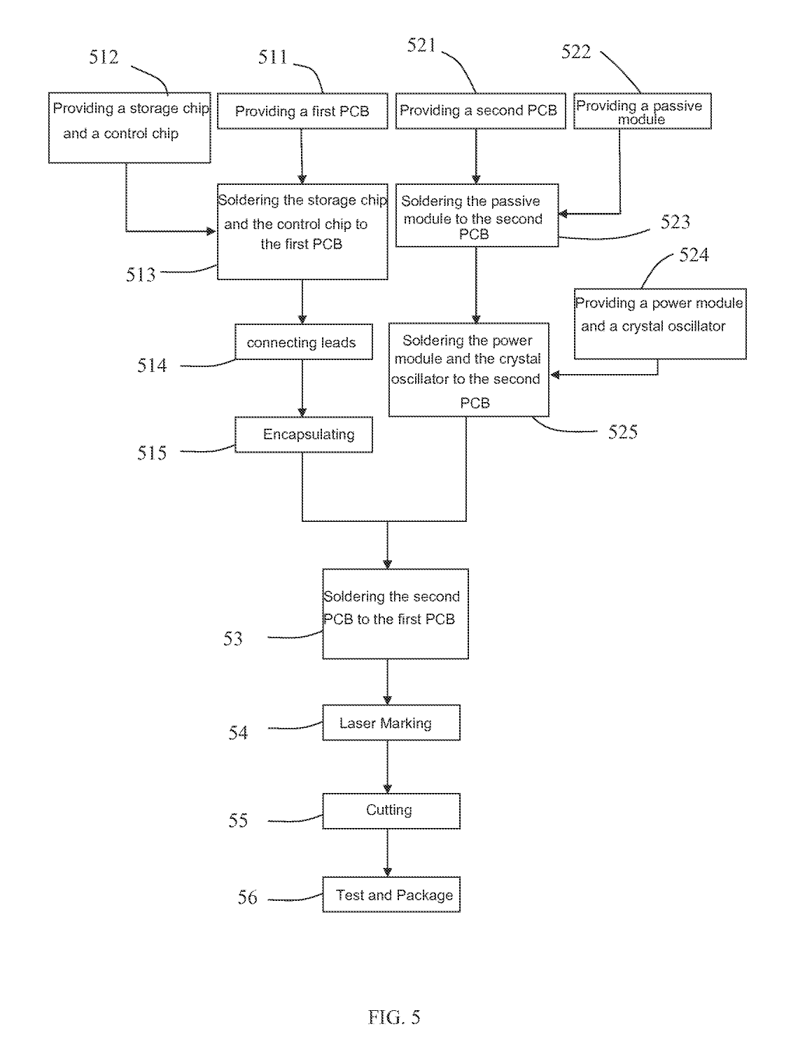

Please refer to FIG. 5, a flow chart of manufacturing the Universal Serial Bus device in accordance with the present invention will be described detailed hereinafter.

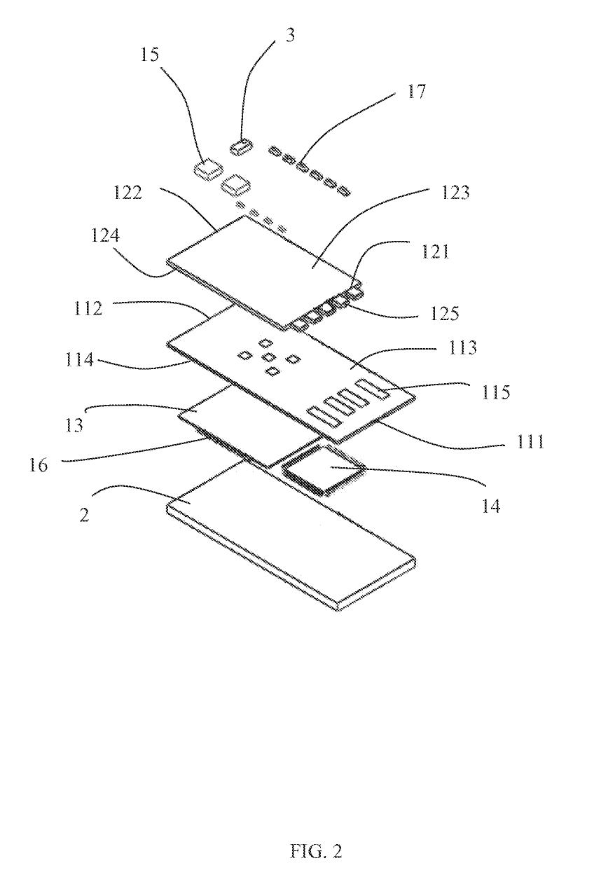

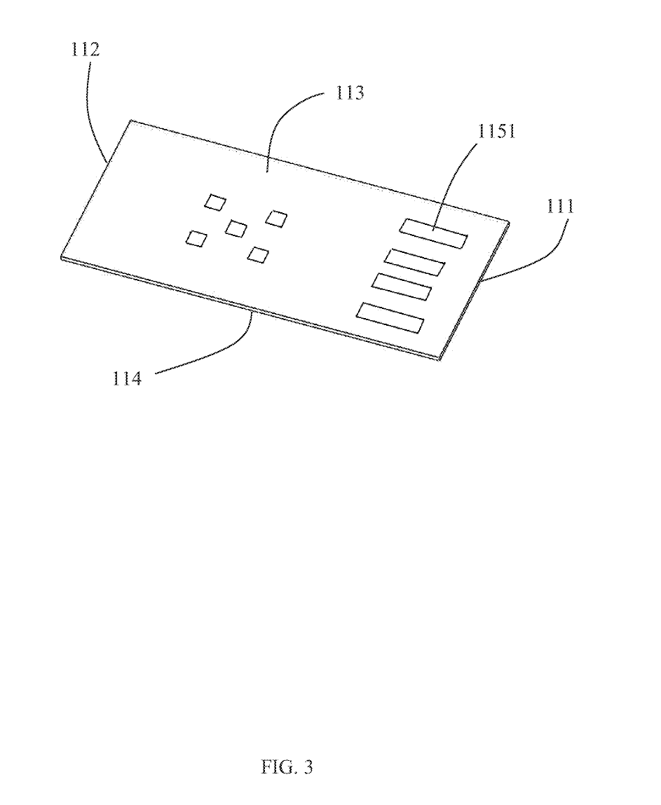

S511: Providing a PCB array for manufacture in mass. In the preferred embodiment of the present invention, the PCB array comprises a plurality of first PCBs 11 arranged on the same plane and each with the same structure and same manufacture process, hence, only one will be taken as an example for description. The detailed structure of the first PCB 11 is as described above and shown in FIGS. 2-3;

S512: Providing at least one storage chip 13 and at least one control chip 14;

S513: The storage chip 13 and the control chip 14 are soldered to the first lower surface 114 of the first PCB 11 via SMT. In an alternative embodiment, more than one storage chips 13 and more than one control chips 14 could be soldered to the first lower surface 114 of the first PCB 11;

S514: Please refer to FIG. 2, electrically connecting the storage chip 13, the control chip 14 with the first PCB 11 through a plurality of leads 16;

S515: injection molding the plastic package shell 2 over the first lower surface 114 of the first PCB 11 to encapsulate the first lower surface 114 and the storage chip 13 and the control chip 14 arranged on the first lower surface 114;

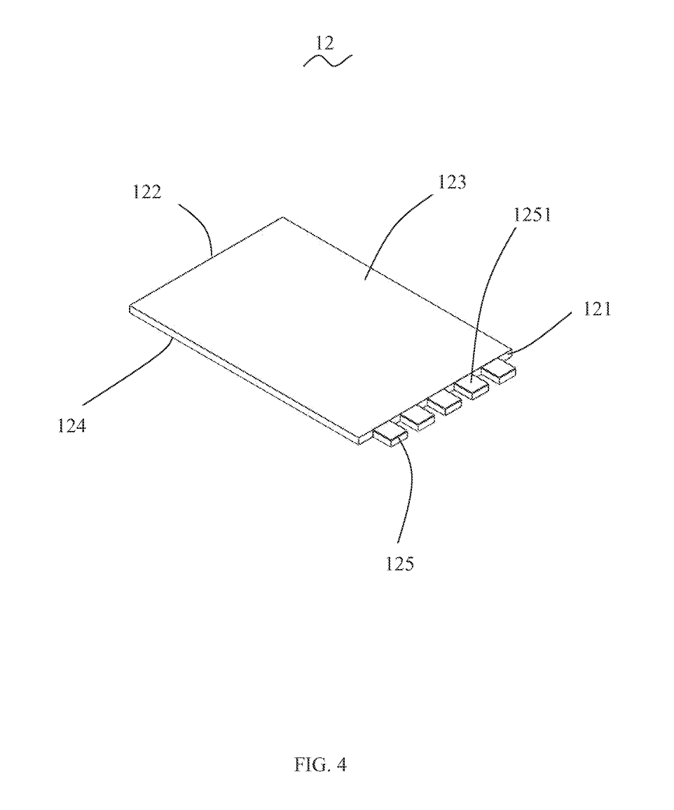

S516: Providing another PCB array for manufacture in mass. In the preferred embodiment of the present invention, the PCB array comprises a plurality of second PCBs 12 arranged on the same plane and each with the same structure and same manufacture process, hence, only one will be taken as an example for description. The detailed structure of the second PCB 12 is as described above and shown in FIGS. 2 and 4;

S522: Providing a passive module 17;

S523: soldering the passive module 17 to the second upper surface 123 of the second PCB 12. For a skilled person in the field, the passive module 17 is relative to an active module. The passive components mainly point to those who do not influence the signal features, and just let the signal go through without any change, usually include resistance, capacitance etc. In the preferred embodiment, the passive module 17 is soldered to the second upper surface 123 of the second PCB 12 via SMT. The process is as follows: Placing solder to corresponding positions on the second upper surface 123 in advance; Mounting the passive module 17 to the corresponding positions on the second upper surface 123 of the second PCB; melting the solder by a reflow soldering equipment, thus soldering the passive module 17 to the second upper surface 123 reliably;

S524: Providing a power module 3 and a crystal oscillator 15;

S525: Soldering the power module 3 and the crystal oscillator 15 to the second upper surface 123 of the second PCB 12 via SMT. In an alternative embodiment, the power module 3 and the crystal oscillator 15 also could electrically connect to the second PCB 12 via leads (not shown);

S53: electrically connecting the first PCB 11 and the second PCB 12 by solder. The second lower surface 124 of the second PCB 12 is so soldered to the first upper surface 113 of the first PCB 11 via SMT, such that the first contacting portions 115 are near to the first front end 111, and the second contacting portions 125 are behind the first contacting portions 115. The second contacting surface 1251 is higher than the first contacting surface 1151 along the thickness direction of the first and second PCBs 11, 12. Also the second contacting portions 125 are attached to the first upper surface 113 of the first PCB 11;

S54: Laser marking on the plastic package shell 2, such as the information of company name, storage capacity etc.;

S55: Cutting the products;

S56: Testing the electricity performance and packing to finish the manufacture of the products.

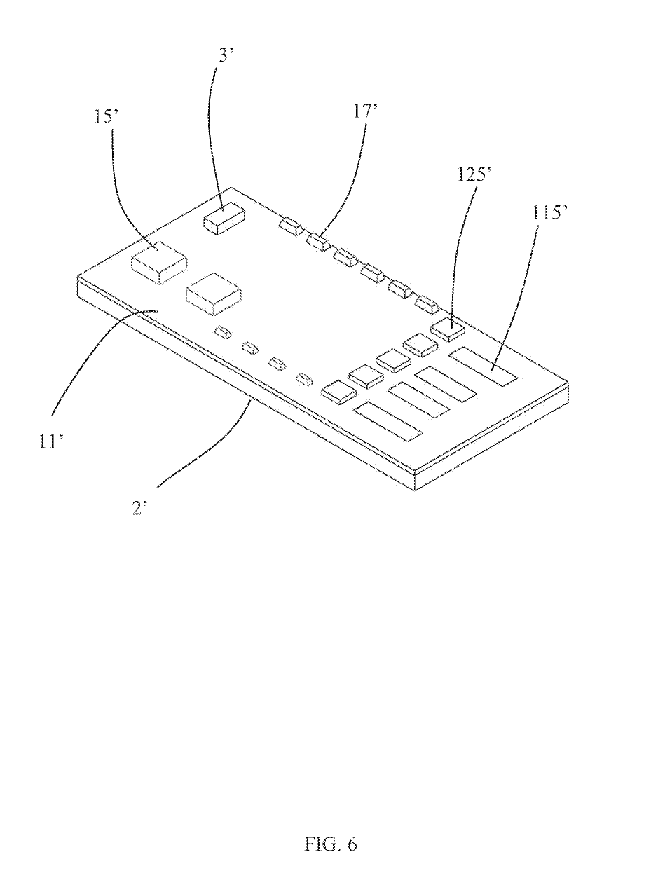

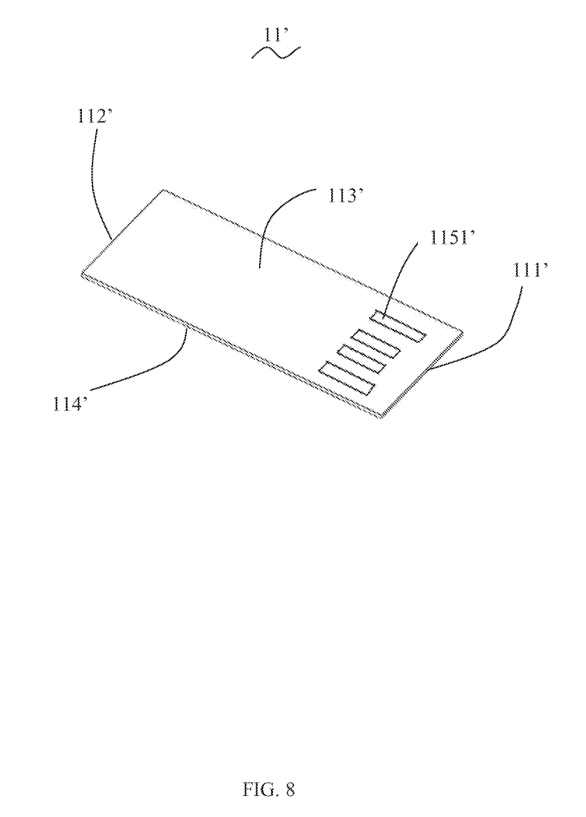

Please refer to FIGS. 6-8, a Universal Serial Bus device (not labeled) in accordance with a second embodiment of the present invention comprises a PCB module (not labeled), a plastic package shell 2′encapsulating the PCB module, and a power module 3′ arranged on the PCB module. The power module 3′ is also exposed to the outside same as the power module 3 in the first embodiment.

The PCB module comprises a PCB 11′, a storage chip 13′ and a control chip 14′ arranged on the first PCB 11′, and a crystal oscillator 15′. Different from the first embodiment, only one PCB 11′ is contained in the PCB module to realize one-channel connection.

The PCB 11′ comprises a front end 111′ and opposite rear end 112′, opposite upper surface 113′ and lower surface 114′, four first contacting portions 115′ arranged in a row on the upper surface 113′, and five second contacting portions 125′ arranged in row on the upper surface 113′ and behind the first contacting portions 115′. Each first contacting portion 115′ has a first contacting surface 1151′ exposed to the outside from the upper surface 113′. Each second contacting portion 125′ is a pad soldered to the upper surface 113′ via SMT. In the preferred embodiment, the first and second contacting portions 115′, 125′ are in the form of golden fingers. In an alternative embodiment, the first contacting portions 115′ also could be elastic metal arms soldered to the upper surface 113′.

The storage chip 13′ and the control chip 14′ are arranged on the lower surface 114′ and soldered to the lower surface 114′ via SMT. The crystal oscillator 15′ is soldered to the upper surface 113′ via SMT.

The plastic package shell 2′ is disposed on the lower surface 114′ to encapsulate the storage chip 13′ and the control chip 14′. In the preferred embodiment, the upper surface 113′ is not encapsulated by the plastic package shell 2′. The crystal oscillator 15′ is arranged on the upper surface 113′ and exposed to the outside. The plastic package shell 2′ is made via injection molding.

The power module 3′ is electrically connected to the upper surface 113′ of the first PCB 11′ and exposed to the outside. The power module 3′ is soldered to the upper surface 113′ via SMT. Since the plastic package shell 2′ does not fully encapsulate the PCB module and the power module 3′ is exposed to the outside, the Universal Serial Bus device in accordance with the second embodiment of the present invention has the advantages of reduced size, lower cost, higher heat-radiation ability and convenient maintenance. Except the advantages above, the cross talk among the signals is also depressed since the power module 3′ and the storage chip 13′, the control chip 14′ are arranged on different surfaces.

It should be noticed that the reason that why the crystal oscillator 15′ is designed to be exposed to the outside is same as that of the power module 3′. Of course, the crystal oscillator 15′ could be arranged on the lower surface 114′ and encapsulated by the plastic package shell 2′.

Same as the first embodiment, the PCB module also comprises a passive module 17′ which comprises at least one capacitance (not labeled), and a plurality of resistance. In the second embodiment, the passive module 17′ is arranged on the upper surface 113′ and exposed to the outside for simplifying the process and reducing cost. Of course, the passive module 17′also could be arranged on the lower surface 114′ together with the storage chip 13′ and the control chip 14′, and encapsulated by the plastic package shell 2′.

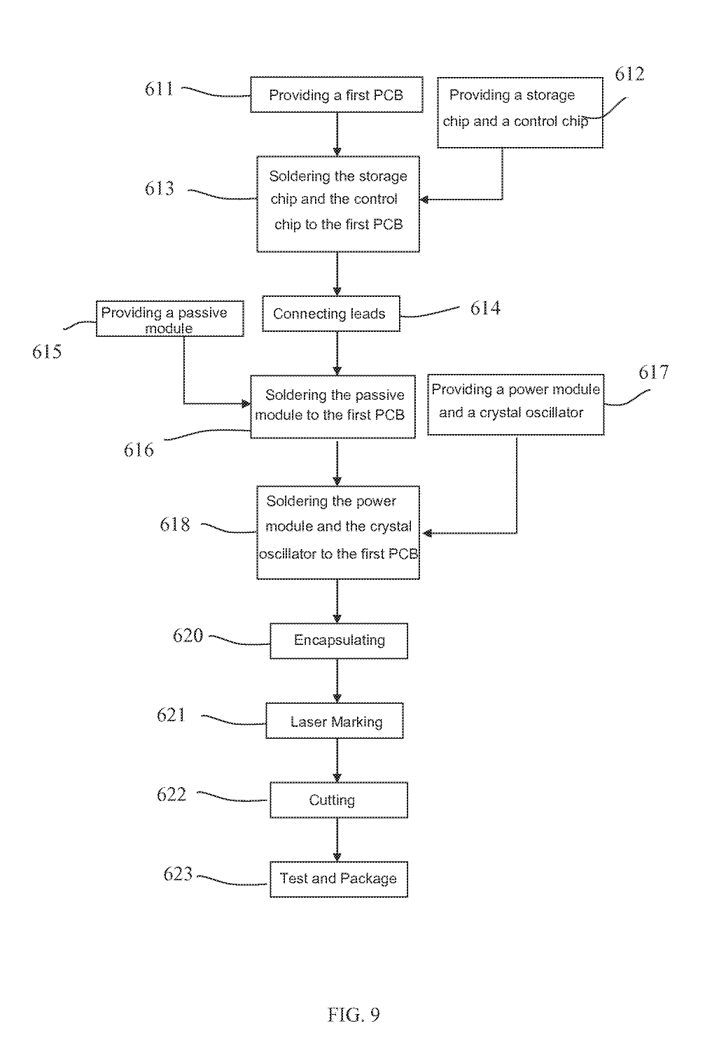

The process flow chart of the Universal Serial Bus device is shown in FIG. 9, the detailed description will be made hereinafter.

Step 611: Providing a PCB array for mass manufacture. In the second embodiment of the present invention, the PCB array comprises a plurality of PCBs 11′ arranged on the same plane and each with the same structure and same manufacture process, hence, only one will be taken as an example for description. The detailed structure of the PCB 11′ is as described above and shown in FIGS. 6-8;

Step 612: Providing a storage chip 13′ and a control chip 14′;

Step 613: soldering the storage chip 13′ and the control chip 14′ to the lower surface 114′ of the PCB 11′ via SMT;

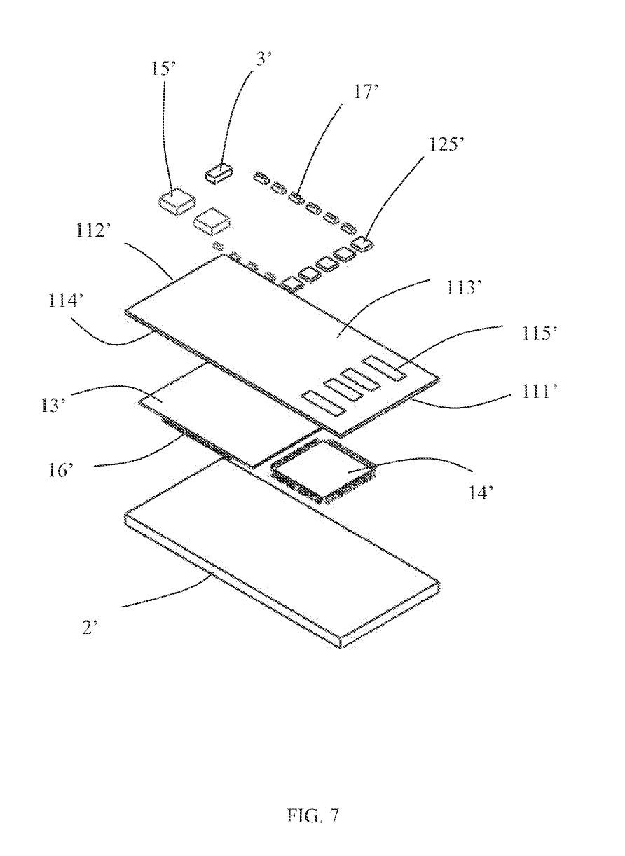

Step 614: electrically connecting the storage chip 13′ and the control chip 14′ with the PCB 11′ via a plurality of leads 16′ (FIG. 7);

Step 615: Providing a passive module 17′;

Step 616: Soldering the passive component 17′ to the upper surface 113′ same as described in the first embodiment and omitted here;

Step 617: Providing a power module 3′ and a crystal oscillator 15′;

Step 618: Soldering the power module 3′ and the crystal oscillator 15′ to the upper surface 113′ via SMT or leads (not shown);

Step 620: Forming the plastic package shell 2′ to the lower surface 114′ of the PCB 11′ via injection molding to encapsulate the storage chip 13′ and the control chip 14′ arranged on the lower surface 114′;

Step 621: Laser Marking on the plastic package shell 2′, such as the information of company name, storage capacity etc.;

S622: Cutting the products;

S623: Testing the electricity performance and packing to finish the manufacture of the products.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed. For example, the tongue portion is extended in its length or is arranged on a reverse side thereof opposite to the supporting side with other contacts but still holding the contacts with an arrangement indicated by the broad general meaning of the terms in which the appended claims are expressed.

We claim:

1. A Universal Serial Bus device, comprising:
a PCB module, comprising a PCB, and a storage chip and a control chip both arranged on the PCB module, the PCB comprising opposite front end and rear end, and opposite upper surface and lower surface, the upper surface having a plurality of contacting portions, and the storage chip and the control chip being arranged on said lower surface;
a plastic package shell at least encapsulating the lower surface of the PCB to encapsulate the storage chip and the control chip; and
a power module electrically connected to the part of the PCB module where is not encapsulated by the plastic package shell.

2. The Universal Serial Bus device as claimed in claim 1, wherein the upper surface of the first PCB is not encapsulated by the plastic package shell, and wherein the power module is soldered to the upper surface via SMT (Surface Mounting Technology).

3. The Universal Serial Bus device as claimed in claim 2, wherein the PCB module further comprises a crystal oscillator arranged on the upper surface of the PCB.

4. The Universal Serial Bus device as claimed in claim 1, wherein the plurality of contacting portions are arranged as at least two rows, four first contacting portions are in the front row, and five second contacting portions are in the rear row, and wherein the arrangement of the first and second contacting portions is fulfill with the interface standard of USB 3.0.

5. The Universal Serial Bus device as claimed in claim 1, wherein the PCB of the PCB module is a first PCB comprising opposite first front and rear ends and opposite first upper and lower surfaces, and wherein the PCB module further comprises a second PCB comprising opposite second front end and second rear end and opposite second upper surface and second lower surface, and wherein the second lower surface of the second PCB is attached to the first upper surface of the first PCB, and the second lower surface of the second PCB is not encapsulated by the plastic package shell with the power module attached thereto.

6. The Universal Serial Bus device as claimed in claim 5, wherein the PCB module further comprises a crystal oscillator attached to the second upper surface of the second PCB.

7. The Universal Serial Bus device as claimed in claim 5, wherein the plurality of contacting portions are arranged into at least two rows, including four first contacting portions close to the first front end of the first PCB and five second contacting portions located behind the first contacting portions, and wherein the arrangement of the first and second contacting portions is fulfill the interface standard of USB 3.0.

8. The Universal Serial Bus device as claimed in claim 7, wherein the length of the second PCB is shorter than that of the first PCB, and wherein the second contacting portions are formed with the second PCB and extend beyond the second PCB to be attached to the first upper surface of the first PCB.

9. A method of manufacturing a Universal Serial Bus device comprising the steps of:
providing a PCB comprising opposite front end and rear end, and opposite upper and lower surfaces, and forming a plurality of contacting portions on the upper surface;
providing a power module, a storage chip and a control chip, soldering the power module to the upper surface, and soldering the storage chip and the control chip to the lower surface; and
forming a plastic package shell to the lower surface of the PCB by injection molding to encapsulate the storage chip and the control chip, while the power chip being exposed to the outside.

10. The method of manufacturing a Universal Serial Bus device as claimed in claim 9, further comprising the step of providing a crystal oscillator soldered to the upper surface and not encapsulated by the plastic package shell to be exposed to the outside.

11. The method of manufacturing a Universal Serial Bus device as claimed in claim 9, wherein the plurality of contacting portions are arranged into at least two rows, including four first contacting portions near to the front end of the PCB and five second contacting portions located behind the first contacting portions, and wherein the arrangement of the first and second contacting portions is fulfill the interface standard of USB 3.0.

12. A method of manufacturing a Universal Serial Bus device comprising the steps of:
providing a first PCB which comprises opposite first front end and first rear end, and opposite first upper surface and first lower surface, and a plurality of first contacting portions arranged on the first upper surface;
providing a storage chip and a control chip which are both arranged on the first lower surface of the first PCB and electrically connect to the first PCB by leads;
forming a plastic package shell by injection molding with the first lower surface of the first PCB to encapsulate the storage chip and the control chip;
providing a second PCB which comprises opposite second front end and second rear end, and opposite second upper surface and second lower surface, and a plurality of second contacting portions arranged on the second PCB;
providing a power module arranged on the second upper surface of the second PCB; and
soldering the second lower surface of the second PCB to the first upper surface of the first PCB via SMT, and wherein the second contacting portions are located behind the first contacting portions.

13. The method of manufacturing the Universal Serial Bus device as claimed in claim 12, further comprising a step of providing a crystal oscillator together with the power module which is also arranged on the second upper surface of the second PCB.

14. The method of manufacturing the Universal Serial Bus device as claimed in claim 12, wherein the length of the second PCB is shorter than that of the first PCB, and wherein the second contacting portions extend beyond the second front end of the second PCB and attach to the first upper surface of the first PCB.

15. The method of manufacturing the Universal Serial Bus device as claimed in claim 14, wherein the number of the first contacting portions is four, while the number of the second contacting portions is five, and wherein the arrangement of the first contacting portions and the second contacting portions is fulfill with the interface standard of USB 3.0.
